(19) United States
(12) Patent Application Publication
(10) Pub. No.: US 2007/0099321 A1
(43) Pub. Date: May 3, 2007

(54) Method for fabricating semiconductor laser device

(76) Inventors: Mamoru Miyachi, Saitama (JP); Yoshinori Kimura, Saitama (JP); Kiyofumi Chikuma, Saitama (JP)

Correspondence Address: ARENT FOX PLLC, 1050 CONNECTICUT AVENUE, N.W., SUITE 400, WASHINGTON, DC, 20036, US

(21) Appl. No.: 10/581,202

(22) PCT Filed: Sep. 27, 2004
(86) PCT No.: PCT/JP04/14089

§ 371 Date: Jun. 1, 2006

(30) Foreign Application Priority Data
Dec. 5, 2003 (JP) 2003-407965

(51) Int. Cl. H01L 21/00; H01L 21/28; H01L 21/3205

(52) U.S. Cl. 438/28; 438/606

(57) ABSTRACT

A first intermediate body is fabricated on a semiconductor substrate. The first intermediate body includes a first lasing portion of a multi-layer stack and a metal adherent layer. A second intermediate body is fabricated on a support substrate. The second intermediate body includes a second lasing portion formed of a multi-layer stack to be less in size than the first lasing portion, and a groove formed adjacent thereto to form a metal adherent layer. Then, with waveguide paths brought into close proximity, the adherent layers of the first and second intermediate bodies are fused to generate an integrated adherent layer, thereby securely adhering the first and second lasing portions to each other. Thereafter, the support substrate is stripped off from the second lasing portion, thereby allowing the adherent layer to be partially exposed. A semiconductor laser device is thus fabricated which has the exposed adherent layer as a common electrode.

### TECHNICAL FIELD

The present invention relates to a method for fabricating a semiconductor laser device which emits a plurality of laser beams of different wavelengths.

### BACKGROUND ART

With the widespread proliferation of digital broadcast or broadband technology, such an era is just around the corner as homes or the like are flooded with a large quantity of digital contents, and higher information recording densities are being demanded. For higher-density media used in optical disc storage systems, 700 MB capacity CDs (Compact Discs) for a light beam of a wavelength of 780 nm have been replaced with 4.7 GB capacity DVDs (Digital Versatile Discs) for a light beam of a wavelength of 650 nm. Further in these days, optical disk systems having a capacity of 20 GB or more have been realized using a light beam of a wavelength of 405 nm.

Even with such a high-density recording system, its pickup has to be provided with a laser for a wavelength of 650 nm as well in order to maintain compatibility with the DVDs that have already become widespread.

Two-wavelength integrated lasers are desired for such a pickup hat is compatible with a plurality of wavelengths in order for he pickup to be reduced in size and weight. However, a GaN-based semiconductor that realizes a laser for a wavelength range of 405 nm and an AlGaInP-based semiconductor that realizes a laser for a wavelength range of 650 nm are significantly different from each other in physical property, and thus not allowed for monolithic integration on the same substrate. For this reason, such a two-wavelength integrated laser has been suggested which has a hybrid structure (Patent Document 1: Japanese Patent Application Laid-Open No. 2001-230502, Patent Document 2: Japanese Patent Application Laid-Open No. 2000-252593, and Patent Document 3: Japanese Patent Application Laid-Open No. 2002-118331).

A two-wavelength integrated laser described in Patent Document 1 (Japanese Patent Application Laid-Open No. 2001-230502) has a first light-emitting element, having a first substrate, for emitting a short-wavelength laser beam (e.g., a wavelength range of 405 nm) and a second light-emitting element, having a second substrate, for emitting a long-wavelength laser beam (e.g., a wavelength range of 650 nm). The first and second light-emitting elements are disposed on top of the other on a support substrate (the so-called sub-mount), thereby realizing a hybrid semiconductor laser device.

Here, the first light-emitting element is mounted on the support substrate so as to locate the light-emitting portion on the support substrate side of the first substrate, while the second light-emitting element is mounted on the first light-emitting element so as to locate the light-emitting portion on the first light-emitting element side of the second substrate.

In a hybrid semiconductor laser device disclosed in Patent Document 2 (Japanese Patent Application Laid-Open No. 2000-252593), the n-electrode and p-electrode of a second laser portion are electrically bonded to the p-electrode and n-electrode of a first laser portion via a fusion metal, respectively, and the substrate on the first laser portion side is then removed. This structure allows the first laser portion and the second laser portion to emit respective laser beams of different wavelengths.

A hybrid semiconductor laser device disclosed in Patent Document 3 (Japanese Patent Application Laid-Open No. 2002-118331) allows a first semiconductor light-emitting element and a second semiconductor light-emitting element to be directly bonded to each other, thereby realizing a hybrid semiconductor laser device. Here, in order to supply current through the bonded faces, one of the semiconductor light-emitting elements is partially etched to thereby expose the contact layer, so that the current is injected through the contact layer.

### DISCLOSURE OF THE INVENTION

### PROBLEMS TO BE SOLVED BY THE INVENTION

As mentioned above, the semiconductor laser device described in Patent Document 1 is configured such that the first light-emitting element and the second light-emitting element are mounted on top of the other on the support substrate. In order to allow current to be injected into the overlapped faces of the first light-emitting element and the second light-emitting element in this structure, each has to be manufactured as a discrete semiconductor chip so as to mount the chip-shaped first and second light-emitting elements on the support substrate on top of the other.

To use the two-wavelength integrated laser as a light source for the pickup of an optical disc, the spacing between the two light-emitting points has to be controlled with high precision (±1 μm or less) However, it is difficult to place the chips in proper alignment to provide high precision control to the spacing between the light-emitting points and the direction of emission. Additionally, all the chips have to be individually aligned, resulting in productivity being decreased.

Furthermore, in the semiconductor laser device of Patent Document 1, the light-emitting portion of the first light-emitting element is mounted on the support substrate in close proximity thereto, and the light-emitting portion of the second light-emitting element is mounted on the first substrate, which is provided on the first light-emitting element, in close proximity to the first substrate.

However, according to this structure, the first substrate having a large thickness is interposed between the first and second light-emitting elements. As described in the aforementioned Patent Document 1, the first substrate (GaN substrate) has a typical thickness of about 100 μm, and thus the light-emitting portion of the first light-emitting element (the position of the light-emitting point) is significantly spaced apart from the light-emitting portion of the second light-emitting element (the position of the light-emitting point).

Accordingly, for example, suppose that the semiconductor laser device is incorporated into a pickup to write or read information. In this case, an optical axis alignment of the emission position of the first light-emitting portion (the position of the light-emitting point) with respect to the optical axis of the optical system forming the pickup causes the emission position of the second light-emitting portion to be greatly dislocated from the optical axis of the optical system, resulting in occurrence of aberration or the like.

An adverse effect caused by such an optical axis misalignment could be eliminated by adding optical components such as a prism to the optical pickup, but with an increase in the number of parts and costs.

In the semiconductor laser device described in Patent Document 2, the p- and n-electrodes of the first laser portion and the n- and p-electrodes of the second laser portion are electrically connected to each other via a fusion metal, respectively. Accordingly, supplying forward drive power to the first laser portion through the fusion metal in order for the first laser portion to lase causes the second laser portion to be reverse biased, whereas supplying forward drive power to the second laser portion through the fusion metal in order for the second laser portion to lase causes the first laser portion to be reverse biased.

Accordingly, allowing one of the first laser portion and the second laser portion to lase causes the other laser portion to be reverse biased, thus leading to the problem of reverse breakdown voltage or reverse leakage current.

The semiconductor laser device described in Patent Document 3 allows the first semiconductor light-emitting element and the second semiconductor light-emitting element to be directly bonded to each other, thereby integrating the two semiconductor lasers. Thus, when at least any one of the semiconductor lasers is a semiconductor light-emitting element having bumps and dips on the surface (e.g., a ridge stripe type semiconductor laser), the faces near the light-emitting point sides cannot be bonded to each other, and thus the spacing between the light-emitting points cannot be reduced. Furthermore, in the semiconductor laser device described in Patent Document 3, two laser wafers are bonded to each other, and thereafter the AlGaInP-based laser side is partially etched together with the GaAs substrate to expose the GaAs contact layer. However, since the current confinement layer, which is located immediately above the contact layer before the etching, is also formed of GaAs, it is extremely difficult to stop the etching at the GaAs contact layer. Additionally, in order to supply current through the bonded faces, it is necessary to allow the current to flow perpendicular to the contact layer. However, since the contact layer is formed of a semiconductor such as GaAs, there is a problem that the electrical resistance of the current flow path is increased.

The present invention was devised in view of these conventional problems. It is therefore an object of the invention to provide a method for fabricating a semiconductor laser device which emits a plurality of laser beams of different wavelengths, and which provides a reduced light-emitting point interspace and improved electrical properties and mechanical precision.

Furthermore, it is another object of the invention to provide a fabrication method for efficiently mass-producing a semiconductor laser device which emits a plurality of laser beams of different wavelengths, and which provides a reduced light-emitting point interspace and improved electrical properties and mechanical precision.

### MEANS TO SOLVE THE PROBLEMS

To achieve the aforementioned objects, an aspect of the invention according to claim 1 provides a method for fabricating a semiconductor laser device which emits a plurality of laser beams of different wavelengths. The method is characterized by comprising: a first process for fabricating a first intermediate body on a semiconductor substrate, including a step of forming a first multi-layer stack having a semiconductor for forming a first lasing portion; a second process for fabricating a second intermediate body on a support substrate, including a step of forming a second multi-layer stack of a semiconductor for forming a second lasing portion and a step of forming a groove in the second multi-layer stack; a third process for fabricating a bonded body by securely adhering a face of the first intermediate body on a side of the first multi-layer stack to a face of the second intermediate body on a side of the second multi-layer stack via an electrically conductive adherent layer; and a fourth process for irradiating the second multi-layer stack with light through the support substrate of the bonded body to separate the support substrate and the second multi-layer stack from each other.

An aspect of the invention according to claim 2 relates to the method for fabricating the semiconductor laser device according to claim 1, the method being characterized in that the light passes through the support substrate and is absorbed by the second multi-layer stack in the vicinity of an interface with the support substrate.

An aspect of the invention according to claim 3 is to provide a method for fabricating a semiconductor laser device which emits a plurality of laser beams of different wavelengths. The method is characterized by comprising: a first process for fabricating a first intermediate body on a semiconductor substrate, including a step of forming a first multi-layer stack having a semiconductor for forming a first lasing portion; a second process for fabricating a second intermediate body on a support substrate, including a step of forming a layer containing at least a light absorption layer, a step of forming a second multi-layer stack of a semiconductor for forming a second lasing portion on the light absorption layer, and a step of forming a groove in the second multi-layer stack; a third process for fabricating a bonded body by securely adhering a face of the first intermediate body on a side of the first multi-layer stack to a face of the second intermediate body on a side of the second multi-layer stack via an electrically conductive adherent layer; and a fourth process for decomposing the light absorption layer by irradiating the light absorption layer with light through the support substrate of the bonded body to strip off at least the support substrate along the decomposed light absorption layer.

An aspect of the invention according to claim 4 relates to the method for fabricating the semiconductor laser device according to claim 3, the method being characterized in that in the second process, the groove is formed to be deeper than a depth from a surface of the second multi-layer stack to the light absorption layer.

An aspect of the invention according to claim 5 relates to the method for fabricating the semiconductor laser device according to claim 3 or 4, the method being characterized in that the light passes through the support substrate and is absorbed by the light absorption layer.

An aspect of the invention according to claim 6 relates to the method for fabricating the semiconductor laser device according to any one of claims 1 to 5, the method being characterized in that at least one of the first process and the second process includes a process for forming the adherent layer on at least one of the face of the first intermediate body on the side of the first multi-layer stack and the face of the second intermediate body on the side of the second multi-layer stack.

An aspect of the invention according to claim 7 relates to the method for fabricating the semiconductor laser device according to any one of claims 1 to 6, the method being characterized in that the first multi-layer stack has a III-V compound semiconductor containing any one of arsenic (As), phosphorus (P), and antimony (Sb) as a group V element or a II-VI compound semiconductor, and in that the second multi-layer stack has a nitride-based III-V compound semiconductor with the group V element being nitrogen (N)

An aspect of the invention according to claim 8 relates to the method for fabricating the semiconductor laser device according to any one of claims 1 to 7, the method being characterized in that the adherent layer is of a metal.

### BRIEF DESCRIPTION OF THE DRAWINGS

FIG. 1 is a schematic view illustrating the structure of a semiconductor laser device fabricated according to a first embodiment;

FIG. 2 is a schematic view illustrating the method for fabricating the semiconductor laser device according to the first embodiment;

FIG. 3 is a schematic view illustrating the structure of a semiconductor laser device fabricated according to a second embodiment and a fabrication method therefor;

FIG. 4 is a schematic view illustrating the structure of a semiconductor laser device fabricated according to a first implementation example;

FIG. 5 is a schematic view illustrating a method for fabricating the semiconductor laser device according to the first implementation example;

FIG. 6 is another schematic view illustrating the method for fabricating the semiconductor laser device shown in FIG. 4;

FIG. 7 is another schematic view illustrating the method for fabricating the semiconductor laser device shown in FIG. 4;

FIG. 8 is a schematic view illustrating a method for fabricating a semiconductor laser device according to a second implementation example;

FIG. 9 is another schematic view illustrating the method for fabricating the semiconductor laser device according to the second implementation example; and

FIG. 10 is another schematic view illustrating the method for fabricating the semiconductor laser device according to the second implementation example.

### BEST MODE FOR CARRYING OUT THE INVENTION

Now, as the best modes for carrying out the present invention, first and second embodiments will be described below with reference to the drawings.

### First Embodiment

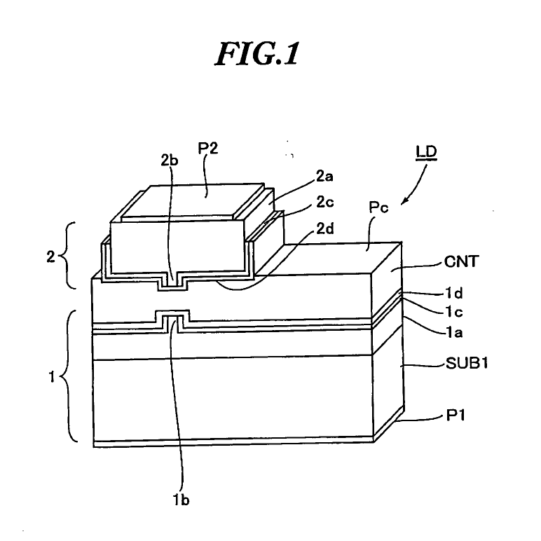

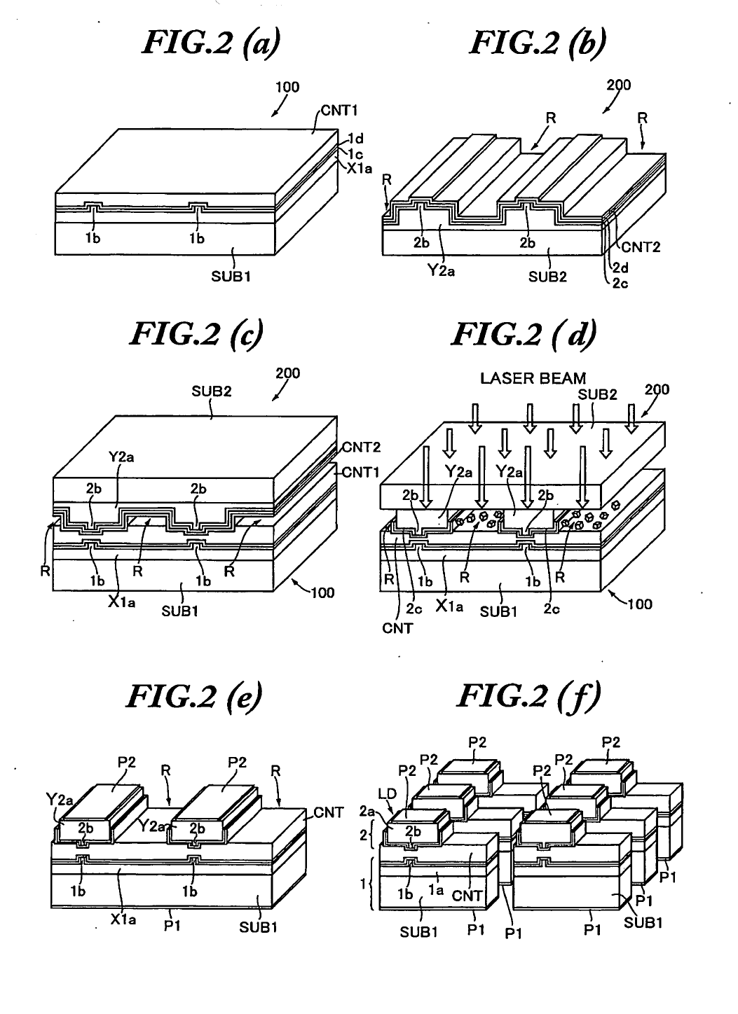

The first embodiment will be described with reference to FIG. 1 and FIG. 2. FIG. 1 is a perspective view illustrating the external structure of a semiconductor laser device fabricated by a fabrication method of this embodiment, and FIG. 2 is a schematic view illustrating the method for fabricating the semiconductor laser device of this embodiment.

Referring to FIG. 1, a semiconductor laser device LD fabricated according to this embodiment includes a first light-emitting element 1 and a second light-emitting element 2 which emit a plurality of laser beams of different wavelengths, wherein the first and second light-emitting elements 1 and 2 are securely adhered integrally to each other by fusion or the like of an adherent layer CNT formed of a metal.

The first light-emitting element 1 includes a semiconductor substrate SUB1 of a III-V compound semiconductor (e.g., GaAs); a first lasing portion la formed, on the semiconductor substrate SUB1, of a first multi-layer stack of a III-V compound semiconductor or a II-VI compound semiconductor; a striped waveguide path 1b formed on a face opposite to the semiconductor substrate SUB1 of the first lasing portion 1a; an insulating film 1c for covering and insulating a region other than the waveguide path 1b; an ohmic electrode layer 1d electrically connected to the waveguide path 1b and formed on the entire surface of the insulating film 1c; and an ohmic electrode layer P1 formed on the back side of the semiconductor substrate SUB1. The first light-emitting element 1 emits a laser beam of a predetermined wavelength from the first lasing portion 1a.

The second light-emitting element 2 includes a second lasing portion 2a formed of a second multi-layer stack of a nitride-based III-V compound semiconductor with the group V element being nitrogen (N); a striped waveguide path 2b formed on a face of the second lasing portion 2a on the adherent layer CNT side; an insulating film 2c for covering and insulating at least a region, other than the waveguide path 2b, facing the adherent layer CNT; an ohmic electrode layer 2d electrically connected to the waveguide path 2b and formed on a region of the insulating film 2c facing the adherent layer CNT; and an ohmic electrode layer P2 formed on a surface of the second lasing portion 2a. The second light-emitting element 2 emits a laser beam of a predetermined wavelength from the second lasing portion 2a.

Now, as will be described later in relation to a fabrication method, a wafer-shaped intermediate body 100 for forming the first light-emitting element 1 and a wafer-shaped intermediate body 200 for forming the second light-emitting element 2 are prefabricated. Then, the ohmic electrode layer 1d formed in the intermediate body 100 and the ohmic electrode layer 2d formed in the intermediate body 200 are securely adhered to each other via the adherent layer CNT, thereby fabricating a bonded body having the integrated intermediate bodies 100 and 200. Thereafter, the bonded body is subjected to predetermined processing for cleavage, thereby making the occupied area of the first light-emitting element 1 larger than the second light-emitting element 2 formed region (in other words, the second light-emitting element 2 is smaller than the first light-emitting element 1). Moreover, the adherent layer CNT is formed on the entire surface of the first light-emitting element 1, thereby being exposed at a region other than the second light-emitting element 2 formed region. Thus, the semiconductor laser device LD is formed in which the exposed adherent layer CNT serves as a common anode.

Additionally, the aforementioned first multi-layer stack allows the first lasing portion 1a to include a double heterostructure (DH) which has a strained quantum well active layer of a III-V compound semiconductor or a II-VI compound semiconductor, and cladding layers deposited so as to sandwich the active layer. Furthermore, there is provided a laser resonator with cleaved facets that are formed by cleaving the first lasing portion 1a at the ends of the waveguide path 1b in its longitudinal direction.

The aforementioned second multi-layer stack allows the second lasing portion 2a to include a double heterostructure (DH) which has a multiple quantum well active layer of a nitride-based III-V compound semiconductor and cladding layers deposited so as to sandwich the active layer. Furthermore, there is provided a laser resonator with cleaved facets that are formed by cleaving the second lasing portion 2a at the ends of the waveguide path 2b in its longitudinal direction.

In the semiconductor laser device LD configured as such, a drive current supplied between an exposed portion Pc of the adherent layer CNT and the ohmic electrode layer P1 flows into the aforementioned active layer in the first lasing portion 1a through the waveguide path 1b, thereby producing light. The light induces carrier recombinations in the aforementioned laser resonator for stimulated emission, thereby allowing a laser beam of a predetermined wavelength (e.g., 650 nm) to be emitted out of the cleaved facets formed on the first lasing portion 1a.

Furthermore, a drive current supplied between the exposed portion Pc of the adherent layer CNT and the ohmic electrode layer P2 flows into the aforementioned active layer in the second lasing portion 2a through the waveguide path 2b, thereby producing light. The light induces carrier recombinations in the aforementioned laser resonator for stimulated emission, thereby allowing a laser beam of a predetermined wavelength (e.g., 405 nm) to be emitted out of the cleaved facets formed on the second lasing portion 2a.

Now, the method for fabricating the semiconductor laser device LD will be described with reference to FIG. 2. FIGS. 2(a) and 2(b) are schematic perspective views illustrating the fabrication processes and structures of the first intermediate body 100 and the second intermediate body 200, respectively. FIG. 2(c) to FIG. 2(f) are schematic perspective views illustrating processes for fabricating the semiconductor laser device LD using the intermediate bodies 100 and 200. Furthermore, in FIGS. 2(a) to (f) , like reference symbols are used to designate the portions that are the same as or corresponding to those of FIG. 1.

The first intermediate body 100 shown in FIG. 2(a) is fabricated as follows. That is, on the wafer-shaped semiconductor substrate SUB1 of a III-V compound semiconductor (e.g., GaAs), a first multi-layer stack X1a of a III-V compound semiconductor or II-VI compound semiconductor is formed which has a double heterostructure. Thereafter, a plurality of striped ridge waveguide paths 1b are formed at predetermined intervals, and then regions of the first multi-layer stack X1a other than the waveguide paths 1b are covered and insulated with the insulating film 1c. Then, the ohmic electrode layer 1d for electrically connecting to the waveguide paths 1b is formed on the insulating film 1c, and an adherent layer CNT1 of a metal is further formed.

The second intermediate body 200 shown in FIG. 2(b) is fabricated as follows. That is, on a sapphire substrate employed as a support substrate SUB2, the second multi-layer stack Y2a of a nitride-based III-V compound semiconductor is formed which has a double heterostructure. Thereafter, a plurality of striped ridge waveguide paths 2b are formed at predetermined intervals, and then each predetermined region between the waveguide paths 2b of the multi-layer stack Y2a is etched to a predetermined depth, thereby forming multi-layer stacks Y2a having a structure with a plurality of stage portions and grooves R located adjacent to each other. Furthermore, regions of the multi-layer stacks Y2a other than the waveguide paths 2b are coated with the insulating film 2c, and then the ohmic electrode layer 2d for electrically connecting to the waveguide paths 2b and the adherent layer CNT2 are sequentially formed.

Additionally, the interval of the ridge waveguide paths 1b of the first intermediate body 100 is equal to the interval of the ridge waveguide paths 2b of the second intermediate body 200.

Then, as shown in FIG. 2(c), the waveguide paths 1b and 2b formed in the first and second intermediate bodies 100 and 200 are opposed to bring the adherent layers CNT1 and CNT2 into close contact with each other. Then, the adherent layers CNT1 and CNT2 at portions in close contact with each other are fused to each other to form the integrated adherent layer CNT as shown in FIG. 1. Thus, the bonded body is fabricated which has the integrated intermediate bodies 100 and 200.

Here, as shown in FIG. 2(b), when the waveguide paths 2b of the multi-layer stacks Y2a are formed of a ridge waveguide path, the adherent layer CNT2 has bumps and dips on the surface thereof. However, as shown in FIG. 2(c), since a metal is fused to affix the adherent layers CNT1 and CNT2 to each other, the waveguide paths 1b and 2b can be brought into close proximity to each other to have an optimal spacing therebetween, without being affected by the aforementioned bumps and dips.

Then, as shown in FIG. 2(d), the support substrate SUB2 is illuminated with a laser beam of a predetermined wavelength (e.g., 360 nm or less) which passes therethrough.

This allows the majority of the laser beam not to be absorbed in the support substrate SUB2 but pass therethrough and absorbed by the multi-layer stacks Y2a in a slight penetration depth. Additionally, because of a significant lattice mismatch between the support substrate SUB2 and the multi-layer stacks Y2a, there exist a large number of crystal defects in a portion of the multi-layer stacks Y2a in contact with the support substrate SUB2 (hereinafter referred to as a “junction vicinity portion”). Accordingly, at the junction vicinity portion of the multi-layer stacks Y2a, the majority of the laser beam is converted into heat, causing the junction vicinity portion to be quickly heated to a high temperature and decomposed. Then, the presence of the pre-formed grooves R causes thin portions of the multi-layer stacks Y2a facing the grooves R to be collapsed due to a force exerted by a gas, thereby allowing the plurality of multi-layer stacks Y2a to be formed being separated by the grooves R.

Then, the bonded body is heated at a predetermined temperature to reduce the cohesive strength of the junction between each of the separated multi-layer stacks Y2a and the support substrate SUB2. Under this condition, the support substrate SUB2 is stripped off, thereby allowing the surface of each of the multi-layer stacks Y2a and the adherent layer CNT facing the grooves R to be exposed.

Then, the exposed surfaces of each of the multi-layer stacks Y2a and the adherent layer CNT are washed, and thereafter, as shown in FIG. 2(e), the ohmic electrode layer P1 is formed on the entire back side of the semiconductor substrate SUB1, and the ohmic electrode layer P2 is formed on the surface of each of the multi-layer stacks Y2a, respectively.

Then, as shown in FIG. 2(f), the entire first and second intermediate bodies 100 and 200 are cleaved along a direction orthogonal to the longitudinal direction of the waveguide paths 1b and 2b, and groove R portions are cleaved in a direction parallel to the longitudinal direction of the waveguide paths 1b and 2b, thereby completing the individual semiconductor laser device LD as shown in FIG. 1.

As described above, according to the fabrication method of this embodiment and the semiconductor laser device LD fabricated according to this fabrication method, the intermediate bodies 100 and 200 that allow for forming a plurality of first and second light-emitting elements 1 and 2 are bonded to each other through the adherent layer CNT in the form of so-called wafers and then cleaved to complete the individual semiconductor laser device LD. Accordingly, by the wafers being bonded to each other, the waveguide paths 1b and 2b can be aligned with high precision and the light-emitting point interspace between the first and second light-emitting elements 1 and 2 can be optimally controlled at a time, thus providing an improved mass productivity.

Furthermore, since both the ohmic electrode layers 1d and 2d of the first and second light-emitting elements 1 and 2 bonded to the adherent layer CNT serve as a p-side electrode, the adherent layer CNT serves as a common anode for supplying a forward bias drive current to the first and second lasing portions 1a and 2a through the ohmic electrode layers 1d and 2d. Accordingly, the configuration of the drive circuit can be simplified; for example, only one switching element has to be connected between the drive current source and the adherent layer CNT to make it possible to supply a drive current to the first and second lasing portions 1a and 2a via the switching element.

Furthermore, supplying a drive current only between the adherent layer CNT and the ohmic electrode layer P1 allows only the first light-emitting element 1 to emit light, while supplying a drive current only between the adherent layer CNT and the ohmic electrode layer P2 allows only the second light-emitting element 2 to emit light. Furthermore, simultaneously supplying a drive current between the adherent layer CNT and the ohmic electrode layer P1 and between the adherent layer CNT and the ohmic electrode layer P2 allows the first and second light-emitting elements 1 and 2 to emit light at the same time. Accordingly, it is possible to provide for a large number of various service versions.

On the other hand, in the multi-wavelength type semiconductor laser described in Japanese Patent Application Laid-Open No. 2000-252593, driving one laser element causes the other laser element to be reverse biased. Accordingly, since the reverse breakdown voltage needs to be taken into account, the semiconductor laser cannot be driven with a large current, and the presence of a reverse leakage current causes an increase in power consumption. However, as described above, the semiconductor laser device LD fabricated according to this embodiment allows for supplying a drive current independently between the adherent layer CNT and the ohmic electrode layer P1 and between the adherent layer CNT and the ohmic electrode layer P2, respectively. This allows the first and second light-emitting elements 1 and 2 to emit light independently. Accordingly, the semiconductor laser device LD fabricated according to this embodiment makes it possible to drive each of the first and second light-emitting elements 1 and 2 with a large current, and reduce the power consumption since the problem of reverse leakage current is not present.

Furthermore, in the fabrication process, the adherent layers CNT1 and CNT2 formed in the first and second intermediate bodies 100 and 200 are bonded to each other, thereby securely adhering the first and second intermediate bodies 100 and 200 integrally to each other via the integrated adherent layer CNT. Accordingly, even when the waveguide paths 1b and 2b having a striped ridge structure are formed causing bumps and dips to occur on the respective surfaces of the ohmic electrode layers 1d and 2d, the adherent layers CNT1 and CNT2 can be easily bonded to each other with a reduced separation spacing between the waveguide paths 1b and 2b. Accordingly, it is possible to realize a semiconductor laser device having an extremely small light-emitting point interspace at improved yield rates.

Furthermore, in the fabrication process, the grooves R are pre-formed on the second intermediate body 200 side as shown in FIG. 2(b). Thus, as shown in FIG. 2(c), affixing the adherent layers CNT1 and CNT2 of the first and second intermediate bodies 100 and 200 to each other causes the adherent layer CNT1 on the first intermediate body 100 side to be exposed to the grooves R. Therefore, for example, without processing the individual semiconductor laser device in any manner after the aforementioned support substrate SUB2 has been stripped off, the adherent layer CNT1 can be easily exposed as a common anode only by stripping off the support substrate SUB2. It is thus possible to realize a simplified fabrication process.

According to the method for fabricating the semiconductor laser device of the aforementioned embodiment, the adherent layer CNT1 is formed in the first intermediate body 100 while the adherent layer CNT2 is formed in the second intermediate body 200. Then, the adherent layers CNT1 and CNT2 are adhered to each other, thereby securely adhering the first and second intermediate bodies 100 and 200 to each other. However, the invention is not limited to this fabrication method. An adherent layer may be formed in any one of the first intermediate body 100 and the second intermediate body 200, and then the first intermediate body 100 and the second intermediate body 200 may be securely adhered to each other via the adherent layer.

Furthermore, the description was given to the case where a sapphire substrate is used as the support substrate SUB2; however, an AlN substrate, a SiC substrate, or an AlGaN substrate may also be used.

### Second Embodiment

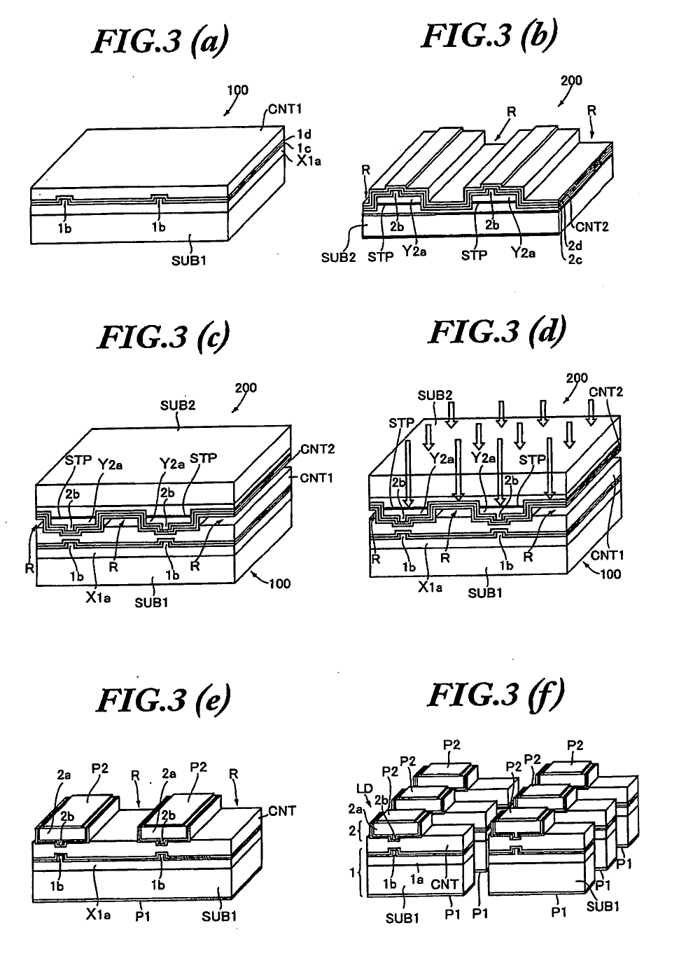

Now, the second embodiment will be described with reference to FIG. 3. FIG. 3 is a schematic view which illustrates a fabrication method according to this embodiment, using like reference symbols to designate the portions that are the same as or corresponding to those of FIG. 2.

A semiconductor laser device fabricated according to this embodiment has basically the same structure as that of the semiconductor laser device shown in FIG. 1, but is fabricated following a different method as discussed below.

That is, the fabrication method proceeds in the following manner. To begin with, the first intermediate body 100 and the second intermediate body 200 shown in FIGS. 3(a) and (b) are pre-fabricated. Here, the first intermediate body 100 shown in FIG. 3(a) is configured in the same manner as the intermediate body 100 shown in FIG. 2(a).

Unlike the intermediate body 200 shown in FIG. 2(b), the second intermediate body 200 shown in FIG. 3(b) is provided with a pre-formed light absorption layer STP for absorbing a laser beam which is emitted to illuminate the support substrate SUB2 in striping it off, as discussed later. The light absorption layer STP is disposed between the support substrate SUB2 and the multi-layer stack Y2a for forming the second lasing portion 2a.

More specifically, in FIG. 3(b), an underlying layer 2ab formed of, e.g., n-type GaN and the light absorption layer STP formed of, e.g., InGaN are deposited on the support substrate SUB2. On the light absorption layer STP, a multi-layer stack Y2a having a double heterostructure of a nitride-based III-V compound semiconductor is formed. A plurality of striped waveguide paths 2b are formed in the multi-layer stack Y2a at the same intervals as those of the waveguide paths 1b of the first intermediate body 100. Then, predetermined regions between each of the waveguide paths 2b of the multi-layer stack Y2a are etched to a depth as far as reaching at least the underlying layer 2ab, thereby forming a plurality of grooves R as well as providing divided multiple multi-layer stacks Y2a. Then, after the insulating film 2c is formed on the surface region other than the waveguide paths 2b, the ohmic electrode layer 2d is formed on the entire surface of the waveguide paths 2b and the insulating film 2c, thereby electrically connecting between the ohmic electrode 2d and the waveguide paths 2b. Furthermore, the adherent layer CNT2 is formed on the ohmic electrode layer 2d, thereby fabricating the second intermediate body 200 as shown in FIG. 3(b).

Then, as shown in FIG. 3(c), the waveguide paths 1b and 2b formed in the first and second intermediate bodies 100 and 200 are opposed to bring the adherent layers CNT1 and CNT2 into close contact with each other. Then, the adherent layers CNT1 and CNT2 at portions in close contact with each other are fused into each other to form the integrated adherent layer CNT, thereby fabricating the bonded body into which the integrated intermediate bodies 100 and 200 are securely adhered integrally to each other.

Then, as shown in FIG. 3(d), the back side of the support substrate SUB2 is illuminated with a laser beam of a predetermined wavelength which passes through the support substrate SUB2 and the underlying layer 2ab. Thus, the laser beam passes through the support substrate SUB2 and the underlying layer 2ab to reach the light absorption layer STP, thereby allowing the light absorption layer STP to be heated and decomposed with the laser beam. This causes the cohesive strength between the underlying layer 2ab and the second lasing portion 2a to be decreased.

Then, the support substrate SUB2 is stripped off from the multi-layer stacks Y2a being separated by the light absorption layer STP, thereby removing the underlying layer 2ab, and the adherent layer CNT2, the ohmic electrode layer 2d, and the insulating film 2c, which are formed in the grooves R, together with the support substrate SUB2. Thus, the surface of each of the multi-layer stacks Y2a and the adherent layer CNT facing the grooves R are exposed.

Then, as shown in FIG. 3(e), the ohmic electrode layer P1 is formed on the entire back side of the semiconductor substrate SUB1, and the ohmic electrode layer P2 is formed on the surface of each of the multi-layer stacks Y2a, respectively. Thereafter, as shown in FIG. 3(f), the entire first and second intermediate bodies 100 and 200 are cleaved along a direction orthogonal to the longitudinal direction of the waveguide paths 1b and 2b, and groove R portions are cleaved in a direction parallel to the longitudinal direction of the waveguide paths 1b and 2b, thereby completing the individual semiconductor laser device LD as shown in FIG. 1.

As described above, according to the fabrication method of this embodiment and the semiconductor laser device LD fabricated according to this fabrication method, the same effects as those of the aforementioned first embodiment can be obtained. Additionally, in the fabrication process, the light absorption layer STP is pre-formed on the second intermediate body 200 side and the back side of the support substrate SUB2 is illuminated with a laser beam of a predetermined wavelength to decompose the light absorption layer STP. Accordingly, the underlying layer 2ab can be removed in conjunction with the support substrate SUB2.

This improves the confinement of light in the active layer and the guide layer of the multi-layer stacks Y2a, and the quality of the radiated beam of laser light.

Furthermore, since the laser beam used to illuminate the back side of the support substrate SUB2 passes through the underlying layer 2ab, the support substrate SUB2 can be formed of the same material as that of the underlying layer 2ab, e.g., GaN. Accordingly, it is possible to form the multi-layer stacks Y2a of a further improved quality.

Furthermore, in pre-forming the grooves R in the second intermediate body 200 shown in FIG. 3(b), the depth of the grooves R can be adjusted so that the thickness from the support substrate SUB2 to the bottom of the grooves R is less than the thickness from the support substrate SUB2 to the light absorption layer STP. In this case, the light absorption layer STP is pre-removed from the underlying layer 2ab portion reduced in thickness due to the grooves R. Accordingly, in the processes for irradiating the back side of the support substrate SUB2 with a laser beam of a predetermined wavelength and for stripping off the support substrate SUB2, the adherent layer CNT1 facing the grooves R can be exposed without collapsing the underlying layer 2ab in the grooves R. It is thus possible to obtain effects such as improved yields.

According to the method for fabricating a semiconductor laser device of the second embodiment described above, the underlying layer 2ab is formed between the support substrate SUB2 and the light absorption layer STP. However, the light absorption layer STP may be directly formed on the support substrate SUB2 without forming the underlying layer 2ab. Even such a fabrication method may also make it possible to fabricate a semiconductor laser device in the same structure as that of the semiconductor laser device shown in FIG. 1.

However, the underlying layer 2ab formed between the support substrate SUB2 and the light absorption layer STP allows for forming high-quality multi-layer stacks Y2a with less crystal defects, and thus it is desirable to form the underlying layer 2ab between the support substrate SUB2 and the light absorption layer STP.

Furthermore, according to the method for fabricating a semiconductor laser device of the second embodiment described above, the adherent layer CNT1 is formed in the first intermediate body 100 while the adherent layer CNT2 is formed in the second intermediate body 200. Then, the adherent layers CNT1 and CNT2 are adhered to each other, thereby fabricating the bonded body having the first and second intermediate bodies 100 and 200 securely adhered to each other. However, the invention is not limited to this fabrication method. An adherent layer may be formed in any one of the first intermediate body 100 and the second intermediate body 200, and then the first intermediate body 100 and the second intermediate body 200 may be securely adhered to each other via the adherent layer.

[First Implementation Example]

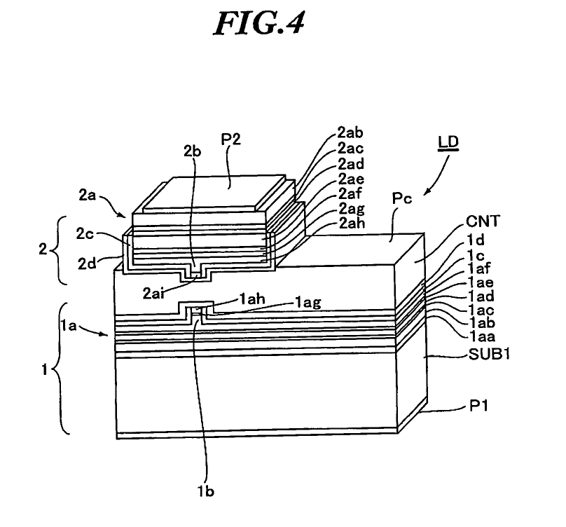

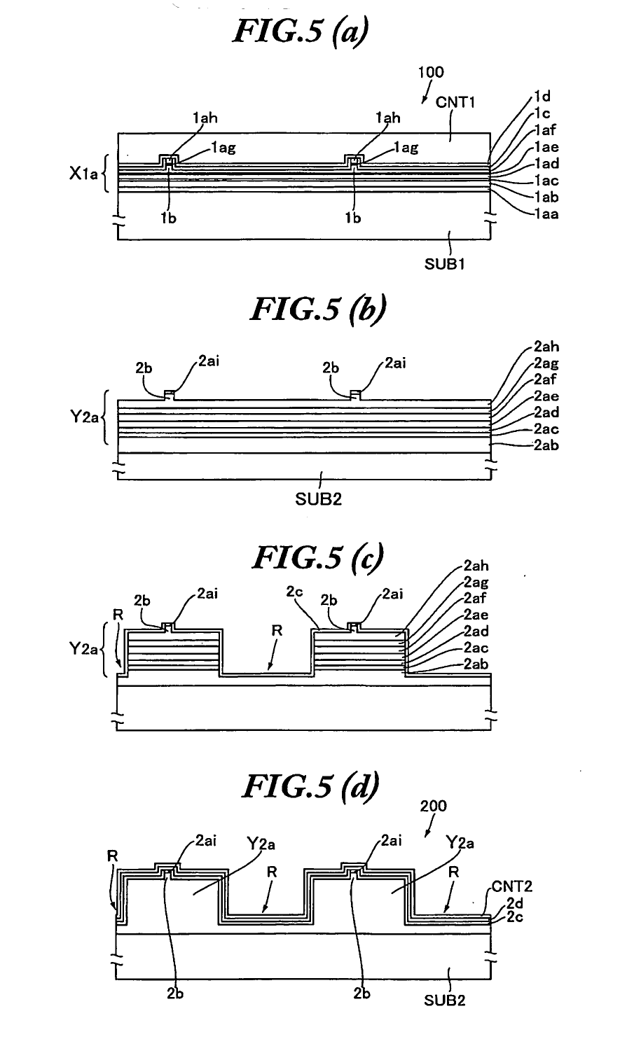

Now, a more specific implementation example according to the first embodiment will be described with reference to FIG. 4 to FIG. 7. FIG. 4 is a schematic cross-sectional view illustrating the structure of a semiconductor laser device fabricated according to this implementation example, while FIGS. 5 to 7 are schematic views illustrating the method for fabricating the semiconductor laser device according to this implementation example. Furthermore, in FIGS. 4 to 7, like reference symbols are used to designate the portions that are the same as or corresponding to those of FIG. 1 and FIG. 2.

In FIG. 4, the semiconductor laser device LD fabricated according to this implementation example includes a first light-emitting element 1 formed on the semiconductor substrate SUB1 and having the first lasing portion 1a, and a second light-emitting element 2 having the second lasing portion 2a. The first and second light-emitting elements 1, 2 are securely adhered integrally to each other by an adherent layer CNT of a fusion metal (e.g., Sn).

The first lasing portion 1a has an n-type buffer layer 1aa, an n-type cladding layer 1ab, an n-type guide layer 1ac, an active layer 1ad having a strained quantum well structure, a p-type guide layer 1ae, a p-type cladding layer 1af, and a p-type current conducting layer 1ag and a p-type contact layer 1ah which are formed on the top portion of the ridge waveguide paths 1b formed in the p-type cladding layer 1af. These layers are deposited on the semiconductor substrate SUB1 of a III-V compound semiconductor (in this implementation example, GaAs).

Furthermore, the insulating film 1c is formed on a region of the p-type cladding layer 1af other than the p-type contact layer 1ah, and the ohmic electrode layer 1d electrically connecting to the p-type contact layer 1ah is formed on the insulating film 1c, with the ohmic electrode layer P1 further formed on the back side of the semiconductor substrate SUB1.

The second lasing portion 2a has a multi-layer stack, which includes an n-type underlying layer 2ab, an n-type cladding layer 2ac, an n-type guide layer 2ad, an active layer 2ae having a multiple quantum well structure, an electron blocking layer 2af, a p-type guide layer 2ag, a p-type cladding layer 2ah, and a p-type contact layer 2ai which is formed on the top portion of the waveguide paths 2b formed in the p-type cladding layer 2ah.

Furthermore, the insulating film 2c is formed on a region of the p-type cladding layer 2ah other than the p-type contact layer 2ai, and the ohmic electrode layer 2d for electrically connecting to the p-type contact layer 2ai is formed on the insulating film 1c, with the ohmic electrode layer P2 further formed on the surface of the n-type underlying layer 2ab.

Furthermore, the ohmic electrode layer 1d on the first lasing portion 1a side and the ohmic electrode 2d on the second lasing portion 2a side are securely adhered to each other with an adherent layer CNT of a fusion metal, thereby allowing for integrating the first and second light-emitting elements 1 and 2. Furthermore, the occupied area of the first light-emitting element 1 is larger than the second light-emitting element 2 formed region. Moreover, the adherent layer CNT is formed on the entire surface of the first light-emitting element 1, thereby being exposed at a region other than the second light-emitting element 2 formed region. Thus, the semiconductor laser device LD is formed in which the exposed adherent layer CNT serves as a common anode.

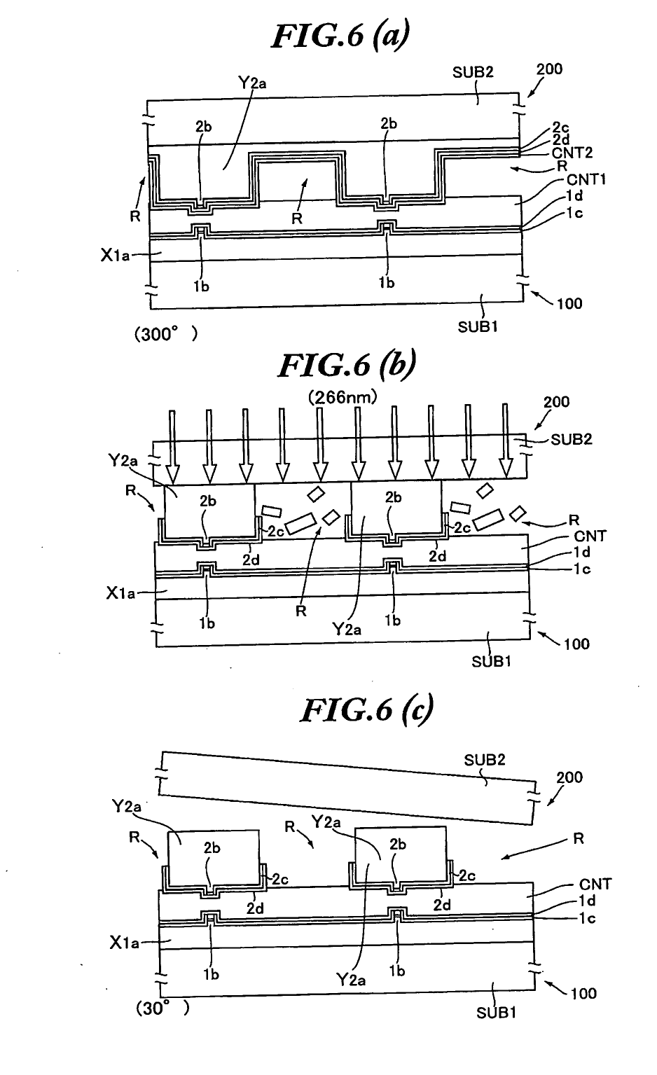

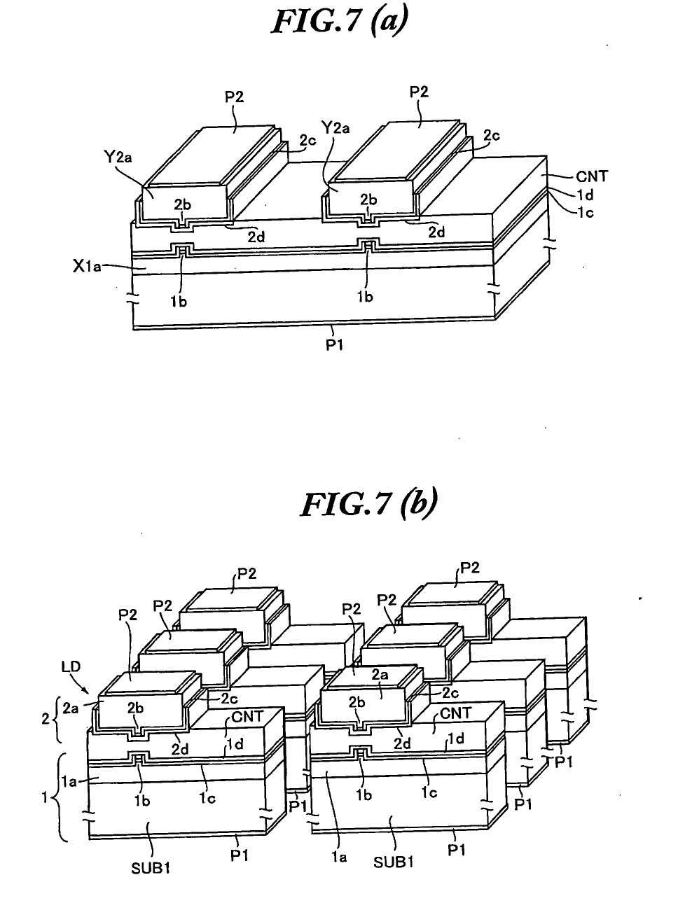

Now, with reference to FIGS. 5 to 7, the method for fabricating the semiconductor laser device LD will be described. FIG. 5(a) is a schematic cross-sectional view illustrating the fabrication process of the first intermediate body 100. FIGS. 5(b) to (d) are schematic cross-sectional views illustrating the fabrication process of the second intermediate body 200. FIGS. 6(a) to (c) and FIGS. 7(a) and (b) are cross-sectional and perspective views illustrating the processes for fabricating the semiconductor laser device LD from the first and second intermediate bodies 100 and 200.

The fabrication process of the first intermediate body 100 will be described with reference to FIG. 5(a). By MOCVD or the like, the buffer layer 1aa of n-type GaAs, which has been turned into an n-type by doping silicon (Si), is deposited in a thickness of about 0.5 μm on the semiconductor substrate SUB1 of a wafer-shaped GaAs (001) substrate. Then, the n-type cladding layer 1ab of n-type Al_{0.35}Ga_{0.15}In_{0.5}P is deposited in a thickness of about 1.2 μm. Then, the guide layer 1ac of AlGaInP is deposited in a thickness of about 0.05 μm. Then, the active layer 1ad of GaInP and AlGaInP having a strained quantum well structure is deposited in a thickness of about a few tens of nm. Then, the guide layer 1ae of AlGaInP is deposited in a thickness of about 0.05 μm. Then, the p-type cladding layer 1af of Al_{0.35}Ga_{0.15}In_{0.5}P, which has been turned into a p-type by doping zinc (Zn), is deposited in a thickness of about 1.2 μm. Then, the p-type current conducting layer 1ag of p-type Ga_{0.51}In_{0.49}P is deposited in a thickness of about 0.05 μm. Then, the p-type contact layer 1ah of p-type GaAs is deposited in a thickness of about 0.2 μm. The multi-layer stack X1a is thus formed which is made from an AlGaInP-based semiconductor.

Then, with a predetermined region being masked to form the waveguide paths 1b, wet etching is carried out from the p-type contact layer 1ah side until the p-type cladding layer 1af has a thickness of about 0.2 μm. Thereby, a plurality of waveguide paths 1b having a striped ridge structure along <110> orientation are formed in the multi-layer stack X1a of an AlGaInP-based semiconductor.

Then, the insulating film 1c of SiO₂ is formed on a region of the p-type cladding layer 1af other than the p-type contact layer 1ah formed on each of the waveguide paths 1b. Thereafter, an ohmic electrode layer 1c of chromium (Cr) or gold (Au) or a stack thereof is formed in a thickness of about 200 nm on the entire surface of the p-type contact layer 1ah and the insulating film 1c, thereby allowing the p-type contact layer 1ah and the ohmic electrode layer 1c to be electrically connected to each other. Then, the adherent layer CNT1 of tin (Sn) serving as a fusion metal is formed on the entire surface of the ohmic electrode layer 1c, thereby fabricating the first intermediate body 100.

Then, the fabrication process of the second intermediate body 200 will be described with reference to FIGS. 5(b) to (d). The MOCVD method or the like is used to deposit a plurality of semiconductor thin films, which are made from GaN-based semiconductors with different compositions and thicknesses, on the support substrate SUB2 of a sapphire substrate, thereby forming a multi-layer stack Y2a of the GaN-based semiconductor with a multiple quantum well active layer and cladding layers.

More specifically, an n-type buffer layer 2aa of GaN or AlN is deposited in a thickness of about a few tens of nm on the sapphire (0001) substrate SUB2. Then, the n-type underlying layer 2ab of n-type GaN, which has been turned into an n-type by doping silicon (Si), is deposited in a thickness of about 5 to 15 μm. Then, the n-type cladding layer 2ac of n-type Al_{0.08}Ga_{0.92}N is deposited in a thickness of about 0.8 μm. Then, then-type guide layer 2ad of n-type GaN is deposited in a thickness of about 0.2 μm. Then, the active layer 2ae is deposited in a thickness of about a few tens of nm, which has a multiple quantum well structure with a well layer and a barrier layer of InₓGa₁₋ₓN (where, 0≦x) having different compositions, for example, In_{0.08}Ga_{0.92}N and In_{0.01}Ga_{0.99}N. Then, the electron blocking layer 2af of Al_{0.2}Ga_{0.8}N is deposited in a thickness of about 0.02 μm. Then, the p-type guide layer 2ag of p-type GaN, which has been turned into a p-type by doping magnesium (Mg), is deposited in a thickness of about 0.2 μm. Then, the p-type cladding layer 2ah of p-type Al_{0.08}Ga_{0.92}N is deposited in a thickness of about 0.4 μm. Then, the p-type contact layer 2ai of p-type GaN is formed in a thickness of about 0.1 μm, thereby forming a multi-layer stack Y2a of a GaN-based semiconductor.

Then, by reactive ion etching (RIE), the multi-layer stack Y2a is etched, excluding the region for forming a striped waveguide path 2b, to such a depth that allows the p-type cladding layer 2ah to have a thickness of about 0.05 μm, thereby forming a plurality of waveguide paths 2b having a striped ridge structure along <11-20> orientation.

Then, predetermined regions between each of the waveguide paths 2b of the multi-layer stacks Y2a are etched to a depth of about 5 μm, thereby forming grooves R that reach the n-type underlying layer 2ab as shown in FIG. 5(c). Thereafter, the insulating film 2c of SiO₂ is formed on a region other than the p-type contact layer 2ai to provide a covering of insulation.

Then, as shown in FIG. 5(d), the ohmic electrode layer 2d of palladium (Pd) or gold (Au) or a stack thereof is formed in a thickness of about 200 nm on the entire surface of the p-type contact layer 2ai and the insulating film 2c, thereby allowing the ohmic electrode layer 2d to be electrically connected to the p-type contact layer 2ai. Then, the adherent layer CNT2 of gold (Au) serving as a fusion metal is formed on the entire surface of the ohmic electrode layer 2d, thereby fabricating the second intermediate body 200.

Then, following the processes shown in FIG. 6 and FIG. 7, the semiconductor laser device LD is fabricated from pre-fabricated intermediate bodies 100 and 200.

First, as shown in FIG. 6(a), the waveguide paths 1b and 2b formed in the first and second intermediate bodies 100 and 200 are opposed to bring the adherent layers CNT1 and CNT2 into close contact with each other. Here, the adherent layers CNT1 and CNT2 are brought into close contact with each other in a manner such that the cleavage plane (110) of the multi-layer stack X1a of the AlGaInP-based semiconductor and the cleavage plane (1-100) of the multi-layer stacks Y2a of the GaN-based semiconductor match with each other, and the waveguide paths 1b of the multi-layer stack X1a of the AlGaInP-based semiconductor and the waveguide paths 1b of the multi-layer stacks Y2a of the GaN-based semiconductor are brought into close proximity to each other.

Then, in a forming gas atmosphere at about 300 degrees centigrade, the entire first and second intermediate bodies 100 and 200 are heated, thereby fusing the close contact portions of the adherent layers CNT1 and CNT2 into an integrated adherent layer CNT.

Then, as shown in FIG. 6(b), the back side of the support substrate SUB2 is illuminated with a laser beam of a wavelength of 360 nm or less. More preferably, the fourth harmonic of YAG laser (a wavelength of 266 nm) is condensed through a predetermined condenser lens into a high-energy light beam, and the resulting beam is allowed to illuminate the back side of the support substrate SUB2, as shown by a number of arrows for convenience purposes.

The majority of the laser beam of a wavelength of 266 nm is not absorbed in the support substrate (sapphire substrate) SUB2 but passes therethrough and is absorbed by the multi-layer stacks Y2a in a slight penetration depth of GaN. Additionally, because of a significant lattice mismatch between the support substrate SUB2 and the GaN, there exist a large number of crystal defects at the GaN junction vicinity portion. Accordingly, at the GaN junction vicinity portion, the majority of the laser beam absorbed is converted into heat, thereby causing the GaN junction vicinity portion to be quickly heated to a high temperature and thus decomposed into metal gallium and nitrogen gases.

Then, the presence of the pre-formed grooves R causes thin portions of the multi-layer stack Y2a of the GaN-based semiconductor in the grooves R to be collapsed due to a force exerted by the aforementioned gas, thereby allowing a plurality of multi-layer stacks Y2a to be formed being separated by the grooves R.

Then, as shown in FIG. 6(c), the entire first and second intermediate bodies 100 and 200 are heated to about 40 degrees centigrade higher than the melting point of gallium to strip the support substrate SUB2 off from each of the multi-layer stacks Y2a.

That is, at the time of irradiating the back side of the support substrate SUB2 with the aforementioned high-energy light, the multi-layer stacks Y2a and the support substrate SUB2 are weakly coupled to each other by the metal gallium. Accordingly, the overall heating to a temperature of about 40 degrees centigrade higher than the melting point of gallium further weakens the coupling condition, thereby stripping off the support substrate SUB2 from each of the multi-layer stacks Y2a.

As shown in FIG. 6(c), stripping off the support substrate SUB2 in this manner causes the surface of each of the multi-layer stacks Y2a and the adherent layer CNT facing the grooves R to be exposed.

Then, the aforementioned collapsed portions are removed by ultrasonic cleaning in pure water, and thereafter the multi-layer stacks Y2a are soaked for about three minutes in a dilute hydrochloric acid to remove the metal gallium which remains on each of the exposed surfaces.

Then, as shown in FIG. 7(a), by vapor deposition or the like, the ohmic electrode layer P2 of titanium (Ti) or Au or a stack thereof is formed on the surface of each of the multi-layer stacks Y2a (the surface of the n-type GaN), and the ohmic electrode layer P1 of an AuGe alloy (an alloy of gold and germanium) is formed on the back side of the n-type GaAs substrate SUB1, respectively,

Then, as shown in FIG. 7(b), the integrated intermediate bodies 100 and 200 shown in FIG. 7(a) are cleaved along the (1-100) plane or the cleavage plane of the multi-layer stacks Y2a of the GaN-based semiconductor, thereby forming a laser resonator. Furthermore, the secondary cleavage is carried out at groove R portions in an orientation perpendicular to the laser resonator plane. In this manner, as shown in FIG. 4, the individual semiconductor laser devices LD are completed, which each have the first and second light-emitting elements 1a and 2a for emitting laser beams of different wavelengths. In the individual semiconductor laser device LD, the occupied area of the first light-emitting element 1 is greater than the second light-emitting element 2 formed region, and the adherent layer CNT is exposed and extends from the first and second light-emitting elements 1 and 2 to serve as a common anode.

According to the semiconductor laser device LD fabricated in accordance with this implementation example, a drive current supplied between the exposed portion of the adherent layer CNT serving as the aforementioned common anode and the ohmic electrode layer P1 causes a laser beam of a wavelength of 650 nm to be emitted through the cleaved facet of the laser resonator formed at the first lasing portion 1a. On the other hand, a drive current supplied between the exposed portion of the adherent layer CNT and the ohmic electrode layer P2 causes a laser beam of a wavelength of 405 nm to be emitted through the cleaved facet of the second lasing portion 2a formed at the laser resonator.

Then, the first and second lasing portions 1a and 2a are fused to each other with the adherent layers CNT1 and CNT2 of a fusion metal. This makes it possible to bring the waveguide paths 1b and 2b into extremely close proximity to each other and thus provide a semiconductor laser device LD having an extremely small light-emitting point interspace.

Furthermore, as shown in FIG. 5(d), in the fabrication process of the second intermediate body 200, the stage-shaped multi-layer stacks Y2a to serve as the second lasing portion 2a when completed and the grooves R adjacent to the stage-shaped multi-layer stacks Y2a are pre-formed. Accordingly, the portion of the adherent layer CNT facing the grooves R can be exposed only by fusing the first and second intermediate bodies 100 and 200 into each other with the adherent layers CNT1 and CNT2 and then, as shown in FIGS. 6(b) and (c), allowing the support substrate SUB2 to be illuminated with a laser beam of a predetermined wavelength to be thereby stripped off.

On the other hand, suppose that with no grooves R formed, the first and second intermediate bodies 100 and 200 are fused into each other with the adherent layers CNT1 and CNT2, and thereafter the support substrate SUB2 is illuminated with a laser beam of a predetermined wavelength and stripped off. In this case, to utilize the fused adherent layer CNT as an electrode, for example, an extremely difficult processing step is required in which the multi-layer stack Y2a side is etched to partially expose the adherent layer CNT. In contrast to this, the fabrication method of this implementation example makes it possible to partially expose the adherent layer CNT with extreme ease, and thus realize improved yields and mass productivity.

Furthermore, as schematically shown in FIG. 6(b), a reduction in thickness of portions of the multi-layer stack Y2a which are collapsed when illuminated with a laser beam of a predetermined wavelength from the back side of the support substrate SUB2 side makes it possible to reduce mechanical damage to each multi-layer stack Y2a that is divided into a plurality of multi-layer stacks Y2a.

As such, a number of effects can be obtained by pre-forming the grooves R in the second intermediate body 200.

In this implementation example, the waveguide paths 1b and 2b are designed as a ridge waveguide path; however, the invention is not limited thereto but may also be applicable to other structures.

Furthermore, although the explanation has been given to the case where a sapphire substrate is used as the support substrate SUB2, it is also acceptable to use an AlN substrate, a SiC substrate, or an AlGaN substrate.

Furthermore, the insulating films 1c and 2c may also be formed of an insulating material such as SiO₂, ZrO₂, or AlN as appropriate.

Furthermore, the fusion metal CNT1 and CNT2 may also be formed of an appropriate combination of Au, In, and Pd.

[Second Implementation Example]

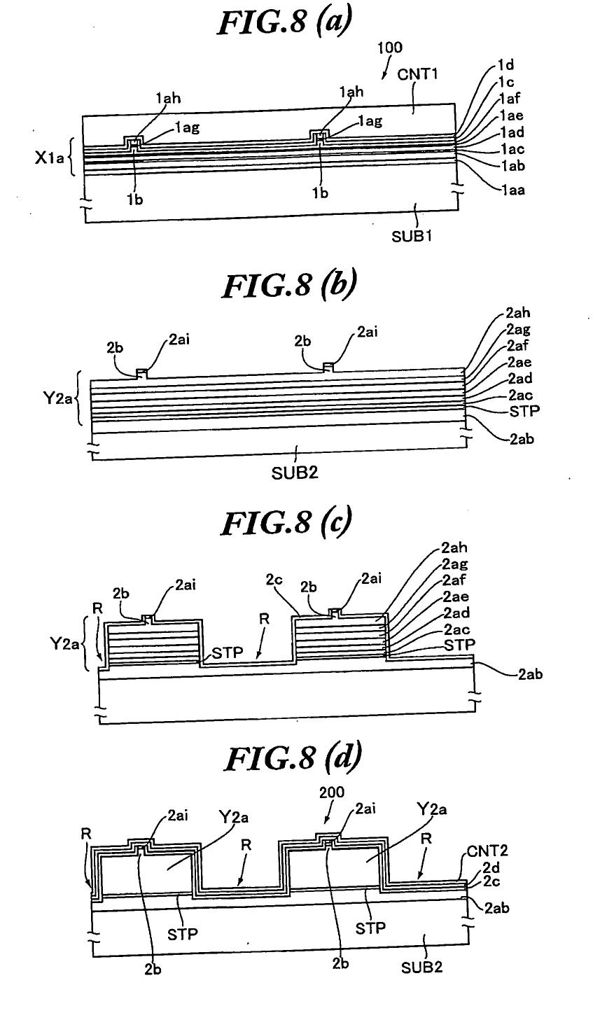

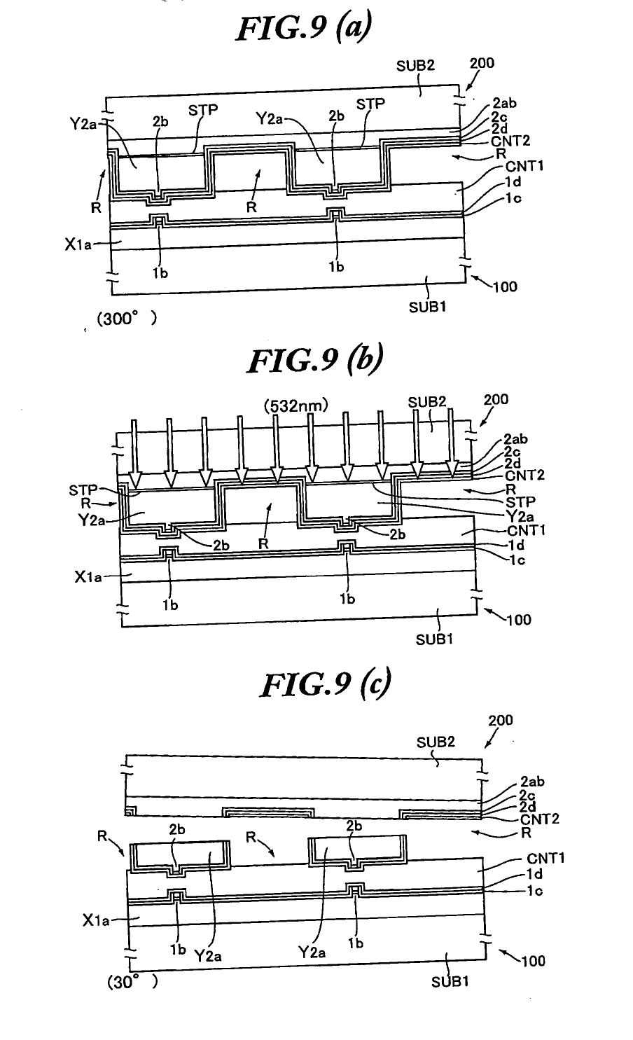

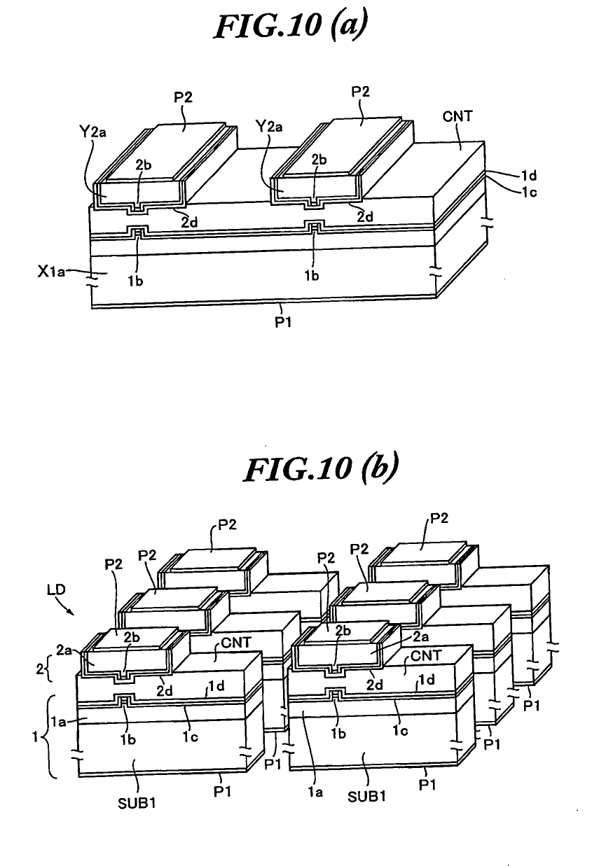

Now, a more specific implementation example according to the second embodiment will be described with reference to FIG. 8 to FIG. 10. FIG. 8(a) is a schematic cross-sectional view illustrating the fabrication process of the first intermediate body 100. FIGS. 8(b) to (d) are schematic cross-sectional views illustrating the fabrication process of the second intermediate body 200. FIGS. 9(a) to (c) and FIGS. 10(a) and (b) are cross-sectional and perspective views illustrating the processes for fabricating the semiconductor laser device LD from the first and second intermediate bodies 100 and 200. Furthermore, in FIGS. 8 to 10, like reference symbols are used to designate the portions that are the same as or corresponding to those of FIG. 4 and FIG. 5 to FIG. 7.

A semiconductor laser device fabricated according to this implementation example has basically the same structure as that of the semiconductor laser device fabricated according to the implementation example shown in FIG. 5 to FIG. 7, but is fabricated following a different method as discussed below.

That is, the method for fabricating the semiconductor laser device LD according to this implementation example proceeds in the following manner. To begin with, the first intermediate body 100 shown in FIG. 8(a) and the second intermediate body 200 shown in FIG. 8(d) are pre-fabricated. Here, the first intermediate body 100 shown in FIG. 8(a) is configured in the same manner as the intermediate body 100 shown in FIG. 5(a).

On the other hand, the fabrication process of the second intermediate body 200 is followed as described below. The MOCVD method or the like is used to deposit, on the support substrate SUB2 of the GaN substrate, the n-type buffer layer 2aa of n-type GaN or AlN, the n-type underlying layer 2ab of n-type GaN, and the light absorption layer STP of InGaN. A plurality of semiconductor thin films, which are made from GaN-based semiconductors with different compositions and thicknesses, are deposited on the light absorption layer STP. A multi-layer stack Y2a of the GaN-based semiconductor is thus formed, which has the aforementioned multiple quantum well active layer and cladding layers.

More specifically, the n-type buffer layer 2aa of GaN or AlN is deposited in a thickness of about a few tens of nm on the GaN(0001) substrate SUB2. Then, the n-type underlying layer 2ab of n-type GaN, which has been turned into an n-type by doping silicon (Si), is deposited in a thickness of about 5 to 15 μm. Then, the light absorption layer STP of In_{0.5}Ga_{0.5}N, doped with carbon (C), is deposited as a non-radiative recombination center. Then, the n-type cladding layer 2ac of n-type Al_{0.08}Ga_{0.92}N is deposited in a thickness of about 0.8 μm. Then, the n-type guide layer 2ad of n-type GaN is deposited in a thickness of about 0.2 μm. Then, the active layer 2ae is deposited in a thickness of about a few tens of nm, which has a multiple quantum well structure with a well layer and a barrier layer of InₓGa₁₋ₓN (where, 0≦x) having different compositions, e.g., In_{0.08}Ga_{0.92}N and In_{0.01}Ga_{0.99}N. Then, the electron blocking layer 2af of Al_{0.2}Ga_{0.8}N is deposited in a thickness of about 0.02 μm. Then, the p-type guide layer 2ag of p-type GaN, which has been turned into a p-type by doping magnesium (Mg), is deposited in a thickness of about 0.2 μm. Then, the p-type cladding layer 2ah of p-type Al_{0.08}Ga_{0.92}N is deposited in a thickness of about 0.4 μm. Then, the p-type contact layer 2ai of p-type GaN is formed in a thickness of about 0.1 μm, thereby forming a multi-layer stack Y2a of a GaN-based semiconductor.

Then, by reactive ion etching (RIE), the multi-layer stack Y2a is etched, excluding the region for forming the striped waveguide path 2b, to such a depth that allows the p-type cladding layer 2ah to have a thickness of about 0.05 μm, thereby forming a plurality of waveguide paths 2b having a striped ridge structure along <1-100> orientation.

Then, predetermined regions between each of the waveguide paths 2b of the multi-layer stacks Y2a are etched, thereby removing the light absorption layer STP to form grooves R that reach the n-type underlying layer 2ab as shown in FIG. 8(c). Then, the insulating film 2c of SiO₂ is formed on a region other than the p-type contact layer 2ai to provide a covering of insulation.

Then, as shown in FIG. 8(d), the ohmic electrode layer 2d of palladium (Pd) orgold (Au) ora stack thereof is formed in a thickness of about 200 nm on the entire surface of the p-type contact layer 2ai and the insulating film 2c, thereby allowing the p-type contact layer 1ah to be electrically connected to the ohmic electrode layer 1c. Then, the adherent layer CNT2 of gold (Au) serving as a fusion metal is formed on the entire surface of the ohmic electrode layer 2d, thereby fabricating the second intermediate body 200.

Then, following the processes shown in FIG. 9 and FIG. 10, the semiconductor laser device LD is fabricated from pre-fabricated intermediate bodies 100 and 200.

First, as shown in FIG. 9(a), the waveguide paths 1b and 2b formed in the first and second intermediate bodies 100 and 200 are opposed to bring the adherent layers CNT1 and CNT2 into close contact with each other. Here, the adherent layers CNT1 and CNT2 are brought into close contact with each other in a manner such that the cleavage plane (110) of the multi-layer stack X1a of the AlGaInP-based semiconductor and the cleavage plane (1-100) of the multi-layer stacks Y2a of the GaN-based semiconductor match with each other, and the waveguide paths 1b of the multi-layer stack X1a and the waveguide paths 2b of the multi-layer stacks Y2a are brought into close proximity to each other.

Then, in a forming gas atmosphere at about 300 degrees centigrade, the entire first and second intermediate bodies 100 and 200 are heated, thereby fusing the close contact portions of the adherent layers CNT1 and CNT2 into an integrated adherent layer CNT.

Then, as shown in FIG. 9(b), the second harmonic of YAG laser (a wavelength of 532 nm) is condensed through a predetermined condenser lens into a high-energy light beam, and the resulting beam is allowed to illuminate the back side of the support substrate SUB2, as shown by a number of arrows for convenience purposes.

The laser beam of a wavelength of 532 nm passes through the support substrate SUB2, the buffer layer 2aa, and the n-type underlying layer 2ab to reach the light absorption layer STP, causing the light absorption layer STP to be heated and decomposed with the laser beam and thereby reducing the cohesive strength between the n-type underlying layer 2ab and each of the multi-layer stacks Y2a.

Then, as shown in FIG. 9(c), the support substrate SUB2 is stripped off being separated by the light absorption layer STP, thereby removing the buffer layer 2aa and the underlying layer 2ab, and the adherent layer CNT2, the ohmic electrode layer 2d, and the insulating film 2c, which are formed in the grooves R, together with the support substrate SUB2. Thus, the surface of each of the multi-layer stacks Y2a and the adherent layer CNT facing the grooves R are exposed.

Then, as shown in FIG. 10(a), by vapor deposition or the like, the ohmic electrode layer P2 of titanium (Ti) or Au or a stack thereof is formed on the surface of each of the multi-layer stacks Y2a (the surface of the n-type GaN), and the ohmic electrode layer P1 of an AuGe alloy (an alloy of gold and germanium) is formed on the back side of the n-type GaAs substrate SUB1, respectively.

Then, as shown in FIG. 10(b), the integrated intermediate bodies 100 and 200 shown in FIG. 10(a) are cleaved along the (1-100) plane or the cleavage plane of the multi-layer stacks Y2a of the GaN-based semiconductor, thereby forming a laser resonator. Furthermore, the secondary cleavage is carried out at groove R portions in an orientation perpendicular to the laser resonator plane, thereby completing the individual semiconductor laser device LD which has basically the same structure as shown in FIG. 4.

As described above, according to the fabrication method of this implementation example and the semiconductor laser device LD fabricated according to this fabrication method, the same effects as those of the aforementioned first embodiment can be obtained. Additionally, in the fabrication process, the light absorption layer STP is pre-formed on the second intermediate body 200 side, and the back side of the support substrate SUB2 is illuminated with a laser beam of a predetermined wavelength to decompose the light absorption layer STP. Accordingly, the underlying layer 2ab can be removed in conjunction with the support substrate SUB2.

This improves the confinement of light in the active layer and the guide layer of the multi-layer stacks Y2a, and the quality of the radiated beam of laser light.

Furthermore, since the laser beam used to illuminate the back side of the support substrate SUB2 passes through the underlying layer 2ab, the support substrate SUB2 can be formed of the same material as that of the underlying layer 2ab, for example, GaN. Accordingly, it is possible to form the multi-layer stacks Y2a of a further improved quality.

Furthermore, in pre-forming the grooves R in the second intermediate body 200 shown in FIG. 8(b), the depth of the grooves R can be adjusted so that the thickness from the support substrate SUB2 to the bottom of the grooves R is less than the thickness from the support substrate SUB2 to the light absorption layer STP. In this case, the light absorption layer STP is pre-removed from the underlying layer 2ab portion reduced in thickness due to the grooves R. Accordingly, in the processes for irradiating the back side of the support substrate SUB2 with a laser beam of a predetermined wavelength and for stripping off the support substrate SUB2, the adherent layer CNT1 facing the grooves R can be exposed without collapsing the underlying layer 2ab in the grooves R. It is thus possible to obtain effects such as improved yields.

In this implementation example, the waveguide paths 1b and 2b are designed as a ridge waveguide path; however, the invention is not limited thereto but may also be applicable to other structures.

Furthermore, although the description has been given to the case where a GaN substrate is used as the support substrate SUB2, it is also acceptable to use a sapphire substrate, an AlN substrate, a SiC substrate, or an AlGaN substrate.

Furthermore, the insulating film 1c and 2c may also be formed of an insulating material such as SiO₂, ZrO₂, or AlN as appropriate.

Furthermore, the fusion metals CNT1 and CNT2 may also be formed of an appropriate combination of Au, In, and Pd.

1. A method for fabricating a semiconductor laser device which emits a plurality of laser beams of different wavelengths, comprising:
a first process for fabricating a first intermediate body on a semiconductor substrate, including a step of forming a first multi-layer stack having a semiconductor for forming a first lasing portion;
a second process for fabricating a second intermediate body on a support substrate, including a step of forming a second multi-layer stack of a semiconductor for forming a second lasing portion and a step of forming a groove in said second multi-layer stack;
a third process for fabricating a bonded body by securely adhering a face of said first intermediate body on a side of said first multi-layer stack to a face of said second intermediate body on a side of said second multi-layer stack side via an electrically conductive adherent layer; and
a fourth process for irradiating said second multi-layer stack with light through said support substrate of said bonded body to separate said support substrate and said second multi-layer stack from each other.

2. The method for fabricating a semiconductor laser device according to claim 1, wherein
said light passes through said support substrate and is absorbed by said second multi-layer stack in the vicinity of an interface with said support substrate.

3. A method for fabricating a semiconductor laser device which emits a plurality of laser beams of different wavelengths, comprising:
a first process for fabricating a first intermediate body on a semiconductor substrate, including a step of forming a first multi-layer stack having a semiconductor for forming a first lasing portion;
a second process for fabricating a second intermediate body on a support substrate, including a step of forming a layer containing at least a light absorption layer, a step of forming a second multi-layer stack of a semiconductor for forming a second lasing portion on said light absorption layer, and a step of forming a groove in said second multi-layer stack;
a third process for fabricating a bonded body by securely adhering a face of said first intermediate body on a side of said first multi-layer stack to a face of said second intermediate body on a side of said second multi-layer stack via an electrically conductive adherent layer; and
a fourth process for decomposing said light absorption layer by irradiating said light absorption layer with light through said support substrate of said bonded body to strip off at least said support substrate along said decomposed light absorption layer.

4. The method for fabricating a semiconductor laser device according to claim 3, wherein
in said second process, said groove is formed to be deeper than a depth from a surface of said second multi-layer stack to said light absorption layer.

5. The method for fabricating a semiconductor laser device according to claim 3, wherein
said light passes through said support substrate and is absorbed by said light absorption layer.

6. The method for fabricating a semiconductor laser device according to claim 1, wherein
at least one of said first process and said second process includes a process for forming said adherent layer on at least one of the face of said first intermediate body on the side of said first multi-layer stack and the face of said second intermediate body on the side of said second multi-layer stack.

7. The method for fabricating a semiconductor laser device according to claim 1, wherein:
said first multi-layer stack has a III-V compound semiconductor containing any one of arsenic (As), phosphorus (P), and antimony (Sb) as a group V element or a II-VI compound semiconductor; and
said second multi-layer stack has a nitride-based III-V compound semiconductor with the group V element being nitrogen (N).

8. The method for fabricating a semiconductor laser device according to claim 1, wherein
said adherent layer is of a metal.
